(19) United States
(12) Patent Application Publication
(10) Pub. No.: US 2022/0376673 A1
(43) Pub. Date: Nov. 24, 2022

(54) BAW RESONATOR ARRANGEMENT WITH RESONATORS HAVING DIFFERENT RESONANCE FREQUENCIES AND MANUFACTURING METHOD

(71) Applicant: RF360 EUROPE GMBH, Munchen (DE)

(72) Inventors: Maximilian SCHIEK, Puchheim (DE); Christian CERANSKI, Munchen (DE); Willi AIGNER, Moosinning (DE)

(21) Appl. No.: 17/770,981

(22) PCT Filed: Oct. 27, 2020
(86) PCT No.: PCT/EP2020/080187

§ 371 Date: Apr. 21, 2022

(30) Foreign Application Priority Data
Oct. 30, 2019 (DE) 10 2019 129 335.9

(51) Int. Cl. H03H 9/17; H03H 3/02; H03H 9/02; H03H 9/54

(52) U.S. Cl. CPC H03H 9/175; H03H 3/02; H03H 9/02007; H03H 9/54; H03H 2003/025; H03H 2003/0435

(57) ABSTRACT

In at least one embodiment, the electric component comprises a first BAW-resonator (1), a second BAW-resonator (2) electrically connected to the first BAW-resonator and a carrier substrate (3) with a top side (30) on which the BAW-resonators are arranged. The first and the second BAW-resonator each comprise a bottom electrode (11,21) and a top electrode (12,22). The bottom electrodes are in each case located between the carrier substrate and the respective top electrode. A first piezoelectric layer (13) is arranged between the top electrode and the bottom electrode of the first BAW-resonator and laterally protrudes from the first BAW-resonator. The second BAW-resonator is mounted on the first piezoelectric layer in a region laterally next to the first BAW-resonator and comprises a second piezoelectric layer (23) between its top electrode and its bottom electrode. The two piezoelectric layers may have different thickness to realize resonators with different resonance frequencies on the same die.

Electric component and method for manufacturing an electric component

An electric component is specified. Furthermore, a method for manufacturing an electric component is specified.

One aspect of the disclosure is directed to the task of providing an electric component with high efficiency. A further task to be solved is to provide a method for easily and inexpensively manufacturing such an electric component.

According to at least one embodiment, an electric component comprises a first BAW-resonator and a second BAW-resonator (BAW=bulk acoustic wave). The second BAW-resonator is electrically connected to the first BAW-resonator. Electrically connected BAW-resonators are resonators in which one electrode of one resonator and one electrode of the other resonator are electrically connected to each other. The first and the second BAW-resonators may be connected in parallel or in antiparallel.

“Connected in parallel” means that the bottom electrodes of the two BAW resonators are electrically connected to each other and, during operation, lie on the same potential. Furthermore the top electrodes of the two BAW-resonators are electrically connected to each other and, during operation, lie on the same potential.

“Connected in anti-parallel” means that the bottom electrode of one BAW-resonator is electrically connected to the top electrode of the other BAW-resonator so that these two electrodes, during operation, lie on the same potential. Furthermore, the top electrode of the one BAW-resonator is electrically connected to the bottom electrode of the other BAW-resonator so that these two electrodes, during operation, lie on the same potential.

According to at least one embodiment, the electric component comprises a carrier substrate with a top side on which the BAW-resonators are arranged. The carrier substrate mechanically carries the BAW-resonators. The carrier substrate is mechanically self-supporting. Lateral surfaces of the carrier substrate, running transversely to the top side, may comprise traces of a chemical or physical material removal, for example sawing grooves.

According to at least one embodiment, the first and the second BAW-resonator each comprise a bottom electrode and a top electrode. The top electrode and the bottom electrode are intended for an alternating voltage, for example with RF frequency, to be applied between them. The top electrodes and the bottom electrodes are in each case electrically connected to a further electric element of the electric component, for example to a further resonator or to a terminal.

During operation of the electric component, an alternating voltage, for example with RF frequency, is applied between the top electrode and the bottom electrode of the respective BAW-resonators. As a result, an alternating electric field is produced between the top electrode and the bottom electrode. A piezoelectric material is arranged between the top electrode and the bottom electrode and is mechanically deformed due to this alternating electric field. Consequently, bulk acoustic waves are produced and propagate in the piezoelectric material. The region between the top electrode and the bottom electrode which is filled with the piezoelectric material is the active region of the BAW-resonator.

The electrodes comprise an electrically conductive material. The electrodes may comprise a metal. For example, the electrodes may each comprise one or more of the following materials: Al, Cu, Ti, Cr, Au, Pt, Ru or Mo. For the purpose of illustration, the electrodes may each have a mean thickness, measured perpendicularly to the top side of the carrier substrate, between 50 nm and 300 nm inclusive.

Here and in the following, the terms “top” and “bottom” as well as “top side” and “bottom side” or similar terms are in no way to be understood as limited to directions antiparallel and parallel to the gravitational direction. Rather, they are generally used, for example to identify opposite areas or objects or directions.

According to at least one embodiment, the bottom electrodes are in each case located between the carrier substrate and their respective top electrode. In a plan view on the top side of the carrier substrate, the top electrode and the bottom electrode of each BAW-resonator overlap with each other.

According to at least one embodiment, a first piezoelectric layer is arranged between the top electrode and the bottom electrode of the first BAW-resonator. The first piezoelectric layer laterally extends or protrudes from the first BAW-resonator.

The first piezoelectric layer may be formed in one piece, i.e. formed integrally. For example, the top electrode and the bottom electrode of the first BAW-resonator are in direct mechanical contact with the first piezoelectric layer. In particular, the first piezoelectric layer completely fills the interspace between the top electrode and the bottom electrode of the first BAW-resonator.

The first piezoelectric layer, for example, comprises one or more of the following materials: AlN or ZnO or AlScN. As an example, a mean thickness of the first piezoelectric layer, measured as its expansion between the top and the bottom electrode of the first BAW-resonator, is at most 5 μm or at most 1 μm or at most 100 nm. Additionally or alternatively, the mean thickness of the first piezoelectric layer is at least 5 nm or at least 50 nm or at least 75 nm.

The first piezoelectric layer laterally extends or protrudes from the first BAW-resonator. This means that the first piezoelectric layer does not only fill the interspace between the top and the bottom electrode of the first BAW-resonator but extends laterally out of this interspace. In other words, the first piezoelectric layer laterally extends beyond the top electrode and/or beyond the bottom electrode of the first BAW-resonator. “Laterally” here and in the following means along a lateral direction, wherein lateral directions are directions parallel to the top side of the carrier substrate. For example, the first piezoelectric layer laterally protrudes from the first BAW-resonator and/or from the top electrode and/or from the bottom electrode by at least 10 μm or at least 50 μm or at least 100 μm. Thus, in a plan view on the top side of the carrier substrate, a portion of the first piezoelectric layer is arranged next to the top electrode and the bottom electrode of the first BAW-resonator and is not overlapping with the top and the bottom electrode. The first piezoelectric layer may be formed contiguously. In plan view on the top side of the carrier substrate, the first piezoelectric layer may cover the top side to at least 75% or at least 90% or completely.

The portion of the first piezoelectric layer filling the interspace between the top electrode and the bottom electrode can be seen as a part of the first BAW-resonator.

The bottom electrode of the first BAW-resonator may be placed directly on the top side of the carrier substrate. Thus, in the region of the first BAW-resonator, the first piezoelectric layer is spaced from the top side of the carrier substrate by the bottom electrode. The portion of the first piezoelectric layer laterally protruding from the first BAW-resonator may lie directly on the top side of the carrier substrate.

According to at least one embodiment, the second BAW-resonator is mounted on the first piezoelectric layer in a region laterally next to the first BAW-resonator. The second BAW-resonator comprises a second piezoelectric layer between the top electrode of the second BAW-resonator and the bottom electrode of the second BAW-resonator.

In other words, in a plan view on the top side of the carrier substrate, the second BAW-resonator is located next to the first BAW-resonator. A portion of the first piezoelectric layer laterally protruding from the first BAW-resonator is arranged between the second BAW-resonator and the carrier substrate. The bottom electrode of the second BAW-resonator may be placed directly on the first piezoelectric layer and the first piezoelectric layer is arranged between the bottom electrode of the second BAW-resonator and the carrier substrate. For example, a mean thickness of the first piezoelectric layer is the same in the region of the first BAW-resonator and in the region between the carrier substrate and the second BAW-resonator.

The portion of the first piezoelectric layer between the second BAW-resonator and the carrier substrate is not intended to form an active region of a resonator. Thus, during the intended operation of the electric component, this portion does not form an active region of a BAW-resonator. An active region of a resonator is a region, in which acoustic waves are intentionally produced and in which these waves propagate. Thus, during the intended operation of the electric component, no acoustic waves are intentionally produced in this portion of the first piezoelectric layer.

The second piezoelectric layer may be formed in one piece. For example, the top and the bottom electrode of the second BAW-resonator are in direct mechanical contact with the second piezoelectric layer. The second piezoelectric layer, for example, comprises one or more of the following materials: AlN or ZnO or AlScN. As an example, a mean thickness of the second piezoelectric layer, measured as its expansion between the top and the bottom electrode of the second BAW-resonator, is at most 5 μm or at most 1 μm or at most wo nm. Additionally or alternatively, the mean thickness of the second piezoelectric layer is at least 5 nm or at least 50 nm or at least 75 nm. The second piezoelectric layer is particularly not formed contiguously with the first piezoelectric layer. The second piezoelectric layer does, for example, not overlap with the first BAW-resonator in a plan view on the top side of the carrier substrate.

Particularly, the second piezoelectric layer does not overlap with the top electrode of the first BAW-resonator.

The top electrodes and/or the bottom electrodes of the BAW-resonators may be laterally spaced apart from each other, for example by at least 10 μm or at least 50 μm or at least 100 μm. The top electrode of the second BAW-resonator is particularly located further away from the carrier substrate than the top electrode of the first BAW-resonator.

The electric component may comprise several first and several second BAW-resonators with each second BAW-resonator being electrically connected to a first BAW-resonator. The features disclosed herein for the one first BAW-resonator and the one second BAW-resonator are also disclosed for all other first and second BAW-resonators, respectively. Particularly, the first piezoelectric layers of all first BAW-resonators may be formed by a common, contiguous first piezoelectric layer. All second BAW-resonators may be mounted on this common first piezoelectric layer.

In at least one embodiment, the electric component comprises a first BAW-resonator, a second BAW-resonator electrically connected to the first BAW-resonator, and a carrier substrate with a top side on which the BAW-resonators are arranged. The first and the second BAW-resonator each comprise a bottom electrode and a top electrode. The bottom electrodes are in each case located between the carrier substrate and the respective top electrode. A first piezoelectric layer is arranged between the top electrode and the bottom electrode of the first BAW-resonator and laterally extends from the first BAW-resonator. The second BAW-resonator is mounted on the first piezoelectric layer in a region laterally next to the first BAW-resonator and comprises a second piezoelectric layer between the top electrode of the second BAW-resonator and the bottom electrode of the second BAW-resonator.

The present disclosure is based, inter alia, on the recognition that for electric filters, like for example ladder type filters, at least two resonators with different resonant frequencies are used. In BAW-resonators, the resonant frequency can be changed by adjusting the stackup or the layer thicknesses. Commonly, detuning layers are added or layers are thinned to shift the resonant frequency of the respective BAW-resonator. In order to achieve the highest possibility effective coupling, it is necessary to achieve an optimal ratio of electrode thickness to piezoelectric layer thickness. Consequently, it is desirable to have different piezoelectric layer thicknesses in different BAW-resonators in order to get different resonant frequencies.

A further aspect to be considered is that for an optimal coupling and thus for high efficiency of the BAW-resonators, the growth conditions for the piezoelectric layers and the electrodes should be optimal. Removing piezoelectric material in the region of a resonator is detrimental as etching deteriorates the growth conditions in that region. Indeed, removal of a grown piezoelectric material effects the quality of the interface to the top electrode. The complete removal of the piezoelectric material plus the bottom electrode to start manufacturing of the whole resonator again is very costly.

As will be explained below, the electric component specified herein can be manufactured without deteriorating the growth conditions. Thus, the BAW-resonators of the electric component have a good coupling and thus a high efficiency. As the second BAW-resonator comprises a second piezoelectric layer, which is different from the first piezoelectric layer of the first BAW-resonator, both BAW-resonators can be chosen to have different resonant frequencies.

According to at least one embodiment, the first piezoelectric layer and the second piezoelectric layer have different thicknesses. Particularly, this concerns the mean thicknesses of the piezoelectric layers in the active regions of the resonators. For example, the thickness of the first piezoelectric layer differs from the thickness of the second piezoelectric layer by at least 2% or at least 5% or at least 10%. As mentioned above, different thicknesses for the piezoelectric layers are advantageous as they allow to have different resonant frequencies for the different BAW-resonators.

According to at least one embodiment, the electric component comprises a dummy electrode located between the second BAW-resonator and the carrier substrate. The dummy electrode may comprise one or more of the materials disclosed in connection with the electrodes of the BAW-resonators. Furthermore, the dummy electrode may have a thickness as specified in connection with the electrodes of the BAW-resonators. For example, the dummy electrode has the same mean thickness and the same material composition as the bottom electrode of the first BAW-resonator. “Same” here and in the following means same within the manufacturing tolerance.

The dummy electrode is located between the second BAW-resonator and the carrier substrate. In this region, the dummy electrode may be located between the first piezoelectric layer and the carrier substrate and may be in direct mechanical contact with both. In a plan view on the top side of the carrier substrate, the dummy electrode, for example, partially or completely overlaps with the top and/or bottom electrode of the second BAW-resonator. The dummy electrode may be separated from the bottom electrode of the first BAW-resonator. Particularly, the dummy electrode may be electrically isolated from the electrodes of the first and second BAW-resonators.

According to at least one embodiment, the bottom electrode of the first BAW-resonator and the dummy electrode lie laterally next to each other in a common plane. Particularly, the common plane extends parallel to the top side of the carrier substrate.

The bottom electrode of the first BAW-resonator and the dummy electrode in each case extend along the common plane. In other words, the bottom electrode of the first BAW-resonator and the dummy electrode have, within the manufacturing tolerance, a common main extension plane. In a plan view on the top side of substrate, the bottom electrode of the first BAW-resonator and the dummy electrode lie next to each other and do not overlap with each other.

According to at least one embodiment, the dummy electrode is not electrically connected to another element or is not intended to be electrically connected for the operation of the electric component. Thus, during the intended operation of the electric component, the dummy electrode is not electrically connected, for example not even to ground. The dummy electrode is a so-called floating electrode. For example, the dummy electrode is electrically isolated from all other elements, particularly from all other electrodes, of the electric component.

According to at least one embodiment, the dummy electrode is completely enclosed by the first piezoelectric layer and the carrier substrate. Thus, no part of the dummy electrode is exposed and freely accessible. Particularly, the dummy electrode is electrically not contactable from the outside, i.e. there is no exposed and freely accessible electrical connection to the dummy electrode.

The dummy electrode together with the portion of the first piezoelectric layer arranged between the dummy electrode and the bottom electrode of the second BAW-resonator advantageously form a mirror, particularly a Bragg mirror, for the acoustic waves produced in the second BAW-resonator. The first piezoelectric layer and the dummy electrode have different acoustic impedances, also called mechanical impedances, for the acoustic waves produced in the second BAW-resonator.

According to at least one embodiment, the first piezoelectric layer is in direct contact to the carrier substrate in the region between the bottom electrode of the second BAW-resonator and the carrier substrate. For example, the protruding portion of the first piezoelectric layer is in direct contact to the carrier substrate everywhere in the region between the bottom electrode of the second BAW-resonator and the carrier substrate.

According to at least one embodiment, the top electrode of the first BAW-resonator and the bottom electrode of the second BAW-resonator lie next to each other in a common plane. Also this common plane may extend parallel to the top side of the carrier substrate. The top electrode of the first BAW-resonator and the bottom electrode of the second BAW-resonator each extend along the common plane. The common plane is a main extension plane of both, the top electrode of the first BAW-resonator and the bottom electrode of the second BAW-resonator. In a plan view on the top side of the carrier substrate, the top electrode of the first BAW-resonator and the bottom electrode of the second BAW-resonator lie next to each other and do not overlap with each other.

For example, the top electrode of the first BAW-resonator and the bottom electrode of the second BAW-resonator have the same mean thickness and the same material composition.

According to at least one embodiment, the electric component is or comprises an RF-filter with the first and the second BAW-resonators being part of the RF-filter. For example, the RF-filter is a bandpass filter, although other filter types are also possible.

A resonant frequency of the first and the second BAW-resonators may be in each case at least 0.5 GHz or at least 1 GHz or at least 5 GHz or at least 6 GHz or at least 8 GHz. The electric component may be a multiplexer comprising several RF-filters. The electric component is, for example, usable in communication devices, like mobile phones.

According to at least one embodiment, the first BAW-resonator is a serial resonator and the second BAW-resonator is a shunt resonator or vice versa. A shunt resonator is also called a parallel resonator. The serial resonator is may be connected to an input or output terminal of the RF-filter. The shunt resonator is, for example, electrically connected to a ground terminal. The RF-filter may have a ladder type topology.

According to at least one embodiment, the carrier substrate comprises layers of different acoustic impedances stacked above each other along a direction perpendicular to the top side. This layer stack is, for example, arranged below the BAW-resonators. In this case, the BAW-resonators may be so called SMRs (solidly mounted resonators).

The layers of different acoustic impedances form a mirror, particularly a Bragg mirror, for the acoustic waves produced and propagating in the BAW-resonators. For example, higher acoustic impedance layers are formed of a metal, like for example W, and lower acoustic impedance layers are formed of a dielectric material, like for example SiO₂. The layers of higher and lower acoustic impedances may be stacked in an alternating manner. One of the dielectric layers may form the top side of the carrier substrate. The metal layers may be embedded between the dielectric layers and are, for example, interrupted in the region between the BAW-resonators in order to avoid additional coupling between the BAW-resonators. One or more metal layers may be uniquely assigned to each of the BAW-resonators. This indicates that, in a plan view on the top side of the carrier substrate, the metal layers only overlap with the assigned BAW-resonator.

The carrier substrate may furthermore comprise a base substrate on which the layers of different acoustic impedances are stacked. The layers of different acoustic impedances are arranged between the base substrate and the BAW-resonators. The base substrate is, for example, the mechanically stabilizing element of the electric component. For example, the base substrate is formed of a semiconductor material, for example of crystalline silicon, or of sapphire.

Alternatively or additionally to the layers of different impedances, the carrier may comprise a recess or cavity in the region below the BAW-resonators. In this case, the BAW-resonators may be so called FBARs (film bulk acoustic resonators).

According to at least one embodiment, the first and the second BAW-resonator have different resonant frequencies. For example, the resonant frequencies of both BAW-resonators differ by at least 5 MHz or at least 10 MHz or at least 30 MHz.

According to at least one embodiment, the electric component is a chip. A chip is to be understood here and in the following as a separately operable and electrically contactable element. A chip is formed, in particular, by being singulated from a wafer composite. For example, the chip comprises a contiguous carrier substrate. Lateral surfaces of the carrier substrate may comprise traces of a material removal resulting from singulating the chip out of the wafer composite. A lateral expansion of the chip is, for example, at most 1% or at most 5% or at most 10% greater than the lateral expansion of the carrier substrate. All electrically functional regions of the chip may be carried by the carrier substrate.

Next, the method for manufacturing an electric component is specified. In particular, the method is suitable for manufacturing an electric component as specified herein. Thus, all features disclosed in connection with the electric component are also disclosed for the method and vice versa.

In at least one embodiment of the method, a carrier substrate is provided in a step A). In a step B), a first electrode layer is deposited on a top side of the carrier substrate. Thereafter, in a step C), a first piezoelectric layer is deposited on the first electrode layer. Thereafter, in a step D), a second electrode layer is deposited on the first piezoelectric layer. Thereafter, in a step E), a second piezoelectric layer is deposited on the second electrode layer. Thereafter, in a step F), a third electrode layer is deposited on the second piezoelectric layer. Thereafter, in a step G), the second piezoelectric layer is removed in the region of a first BAW-resonator. At least a portion of the third electrode layer and of the second piezoelectric layer is kept in a region of a second BAW-resonator.

At least some of the different layers, particularly the piezoelectric layers, may be deposited such that they completely cover the layers deposited before. For example, the mentioned layers are first deposited as contiguous layers without interruptions. Afterwards, the layers, particularly the metal layers, may be structured. For example, the mentioned layers are deposited directly onto each other.

Removing the second piezoelectric layer in the region of the first BAW-resonator may be done by etching as an example. A mask, for example a photolithography mask, may be used to remove the second piezoelectric layer in the region of the first BAW-resonator and to keep and not attack the second piezoelectric layer in the region of the second BAW-resonator. In step F), the third electrode layer may also be deposited in the region of the first BAW-resonator. In this case, the third electrode layer may be removed in the region of the first BAW-resonator before or together with the second piezoelectric layer in step G). The first piezoelectric layer is not removed in the region of the first BAW-resonator.

The features disclosed in connection with the electrodes of the BAW-resonators, particularly concerning the materials and the thicknesses, are also disclosed for the electrode layers.

According to at least one embodiment, a bottom electrode of the first BAW-resonator is formed out of the first electrode layer. For example, an etching process is applied after step B) and before step C) in order to form the bottom electrode of the first BAW-resonator out of the first electrode layer. Alternatively, a lift-off process is applied between steps B) and C) to form the bottom electrode of the first BAW-resonator. In the step of forming the bottom electrode of the first BAW-resonator, the first electrode layer may be removed in all remaining regions of the top side of the carrier substrate not intended for a first BAW-resonator so that only the bottom electrode(s) of the first BAW-resonator(s) remain.

According to at least one embodiment, a dummy electrode is formed out of the first electrode layer in the region of the second BAW-resonator. The dummy electrode may be formed in a common step together with the bottom electrode of the first BAW-resonator. The same processes disclosed for forming the bottom electrode may be used for forming the dummy electrode. By forming the bottom electrode of the first BAW-resonator and the dummy electrode, the first metal layer is interrupted in the region between these two electrodes.

According to at least one embodiment, a top electrode of the first BAW-resonator and a bottom electrode of the second BAW-resonator are formed out of the second electrode layer. These electrodes may again be formed by etching or by lift-off. In the region between these electrodes, the second electrode layer is interrupted. Forming the top electrode of the first BAW-resonator and the bottom electrode of the second BAW-resonator may be done in one step. For example, this step is executed after step D) and before step E).

According to at least one embodiment, a top electrode of the second BAW-resonator is formed out of the third electrode layer. Again, this can be done by etching or by lift-off. Forming the top electrode of the second BAW-resonator may be done after step F) and before or simultaneously with step G).

According to at least one embodiment, the electrode layers and/or the piezoelectric layers are deposited by sputtering or vapor deposition. Different deposition methods may be used for different layers. The piezoelectric layers may be deposited by sputtering.

The described method is advantageous in view of the quality of the resulting BAW-resonators. In particular, each of the BAW-resonators are not grown/formed in the region where an etching process has been applied before. Thus, the growing conditions are very good for both BAW-resonators, which is advantageous in view of the efficiency of the resulting BAW-resonators.

Further preferred embodiments and developments of the electric component and of the method for manufacturing an electric component are described in the following in connection with the Figures. Equal or similar elements as well as elements of equal function are designated with the same reference signs in the Figures. The Figures and the proportions of the elements shown in the Figures are not to be regarded as being true to scale. Rather, single elements, in particular layers, can be shown exaggerated in magnitude for the sake of better representation and/or better understanding.

In the Figures:

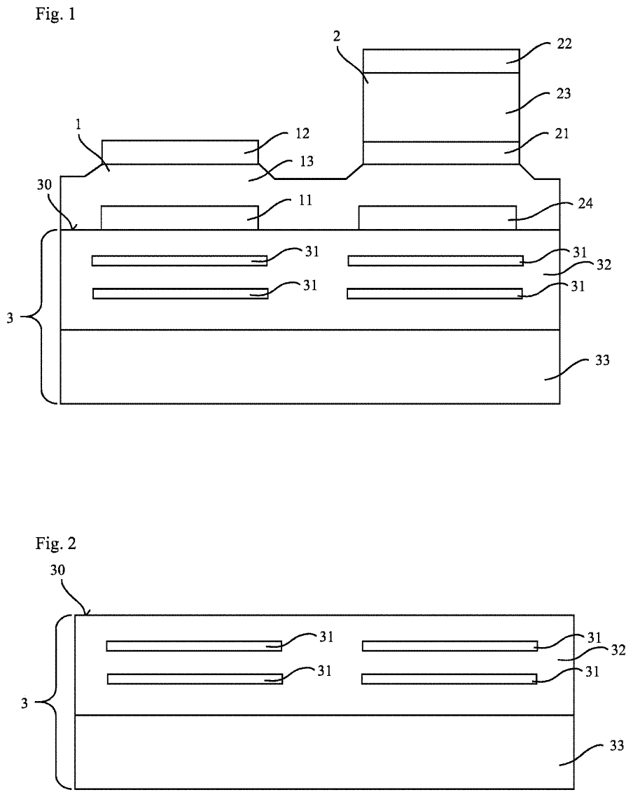

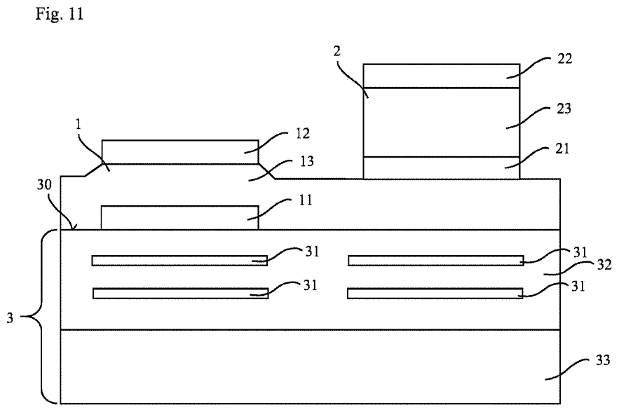

FIGS. 1 and 11 show exemplary embodiments of the electric component in cross-sectional views,

FIGS. 2 to 10 show different positions in an exemplary embodiment of the method for manufacturing an electric component.

FIG. 1 shows a first exemplary embodiment of an electric component in a cross-sectional view. The electric component comprises a carrier substrate 3 with a base substrate 33. The base substrate 33 is, for example, formed of crystalline Si. On top of the base substrate 33, layers 31, 32 of different acoustic impedances are stacked one above the other. The layer stack comprises layers of higher acoustic impedance 31 and layers of lower acoustic impedance 32 stacked above each other in an alternating manner. The layers 31 are, for example, made of W, the layers 32 are, for example, made of SiO₂. The layer stack terminates with a layer 32 forming a top side 30 of the carrier substrate 3.

On the top side 30 of the carrier substrate 3, two BAW-resonators 1, 2 are arranged laterally next to each other. The first BAW-resonator 1 comprises a bottom electrode 11 and a top electrode 12, wherein the bottom electrode 11 is arranged between the top electrode 12 and the carrier substrate 3. Between the top electrode 12 and the bottom electrode 11, a first piezoelectric layer 13 is arranged. The first piezoelectric layer 13 is, for example, made of AlN. The electrodes 11, 12, for example, comprises Al. The region between the electrodes 11, 12 is filled with the first piezoelectric layer 13 and forms an active region of the first BAW-resonator 1, in which bulk acoustic waves are created and propagate during operation.

The first piezoelectric layer 13 does not only fill the region between the electrodes 11, 12 but laterally extends out of this region so that it laterally protrudes from the first BAW-resonator 1. The second BAW-resonator 2 is mounted on a laterally protruding portion of the first piezoelectric layer 13. The second BAW-resonator 2 comprises a top electrode 22 and a bottom electrode 21 as well as a second piezoelectric layer 23 located between the electrodes 21, 22. Also here, the region between the electrodes 21, 22 filled with the second piezoelectric layer 23 forms an active region of the second BAW-resonator 2 for the creation and propagation of bulk acoustic waves. The second piezoelectric layer 23 may again be AlN, the electrodes 21, 22 may again comprise Al.

In FIG. 1, the thickness of the second piezoelectric layer 23 is larger than the thickness of the first piezoelectric layer 13. Particularly, the two BAW-resonators 1, 2 have different resonant frequencies. In an aspect, the thickness of the first piezoelectric layer 13 is constant over its entire lateral expansion. However, in other embodiments the thickness may be similar.

Between the first piezoelectric layer 13 and the carrier substrate 3, a dummy electrode 24 is located in the region of the second BAW-resonator 2. The dummy electrode 24 is not intended for an electrical connection during the operation of the electric component (floating electrode). For example, the dummy electrode 24 is completely enclosed by the first piezoelectric layer 13 and the carrier substrate 3, and there is no possibility for an external electrical connection of the dummy electrode 24. The dummy electrode 24 may be substantially identical to the bottom electrode 11 in terms of its thickness and material composition.

The layer stacks of layers 31, 32 of different acoustic impedances arranged below the first and second BAW-resonators 1, 2 in each case form a Bragg mirror for the acoustic waves produced in the BAW-resonators 1, 2. The first piezoelectric layer 13 and the dummy electrode 24 extending in the region below the second BAW-resonator 2 additionally contribute to the Bragg mirror for the second BAW-resonator 2. Particularly, the dummy electrode 24 and the first piezoelectric material 13 have different acoustic impedances.

FIG. 2 shows a first position in a method for manufacturing an electric component. In this position, a carrier substrate 3 is provided, which is identical to the carrier substrate 3 of FIG. 1. The top side 30 of the carrier substrate 3 is exposed.

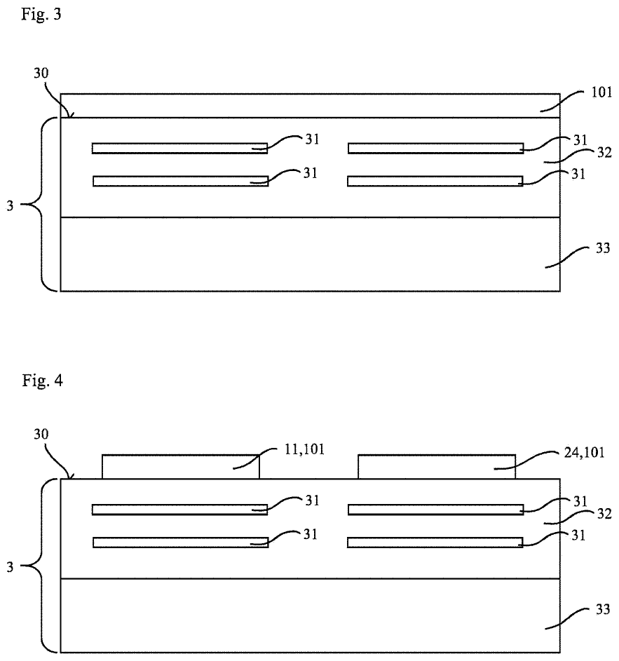

FIG. 3 shows a second position in the method, in which a first electrode layer 101 is deposited directly on the top side 30. The first electrode layer 101 may be applied by sputtering or evaporation.

FIG. 4 shows a third position in the method, in which the first electrode layer 101 is structured into a bottom electrode 11 of a first BAW-resonator and a dummy electrode 24 of a second BAW-resonator. Structuring can, for example, be done with the help of a photolithographic mask and an etching process. The electrodes 11, 24 are separated and electrically isolated from each other. The electrodes 11, 24 lie in and extend along a common plane.

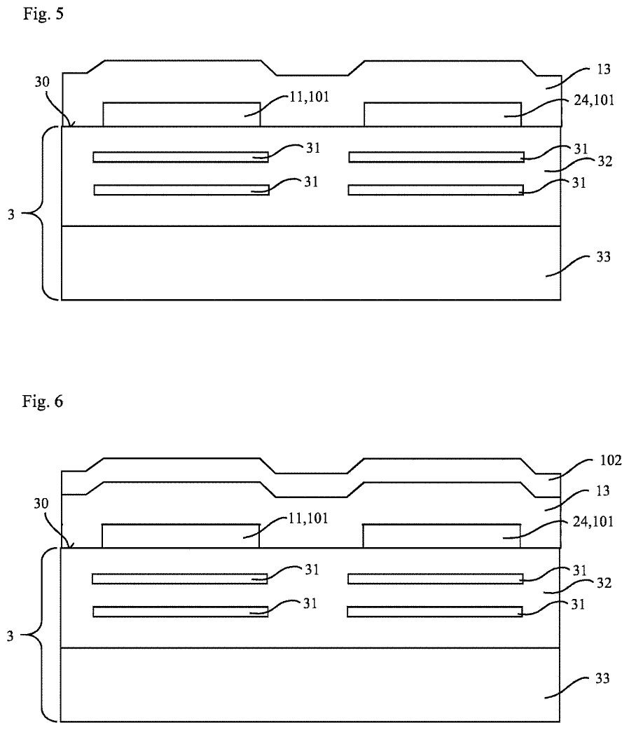

FIG. 5 shows a fourth position in the method, in which a first piezoelectric layer 13 is deposited on the first electrode layer 101 or on the electrodes 11, 24, respectively. The first piezoelectric layer 13 may be applied by sputtering or evaporation. The first piezoelectric layer 13 is deposited as a contiguous layer completely covering the electrodes 11, 24. A thickness of the first piezoelectric layer 13 is constant along its lateral expansion.

FIG. 6 shows a fifth position in the method, in which a second metal layer 102 is deposited on the first piezoelectric layer 13. Again, the second metal layer 102 may be deposited by sputtering or evaporation. For example, the second metal layer 102 is deposited such that, in a plan view, it completely covers the electrodes 11, 24.

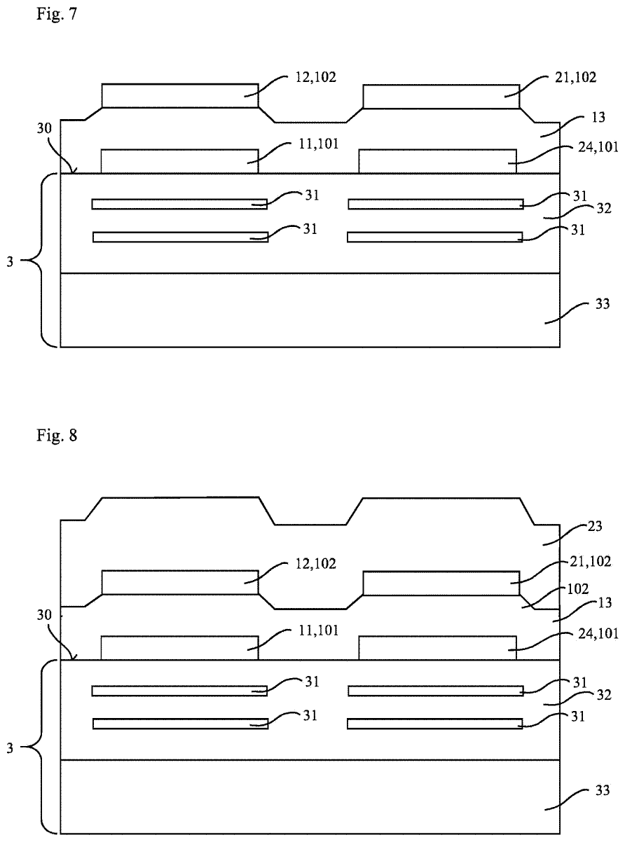

FIG. 7 shows a sixth position in the method, in which the second metal layer 102 is structured into a top electrode 12 of the first BAW-resonator and a bottom electrode 21 of the second BAW-resonator. Structuring is, for example, done with the help of a mask and an etching process. The electrodes 12, 21 may be separated and electrically isolated from each other. In a plan view onto the top side 30 of the carrier substrate 3, the electrode 12 overlaps with electrode 11 and the electrode 21 overlaps with the dummy electrode 24. The electrodes 12 and 21 lie in and extend along a common plane.

FIG. 8 shows a seventh position in the method, in which a second piezoelectric layer 23 is deposited on the second metal layer 102 or on the electrodes 12, 21, respectively. The second piezoelectric layer 23 is deposited as a contiguous layer completely covering the electrodes 12, 21. The second piezoelectric layer 23 is deposited with a constant thickness over its entire lateral expansion. The second piezoelectric layer 23 is, for example, applied by sputtering or evaporation.

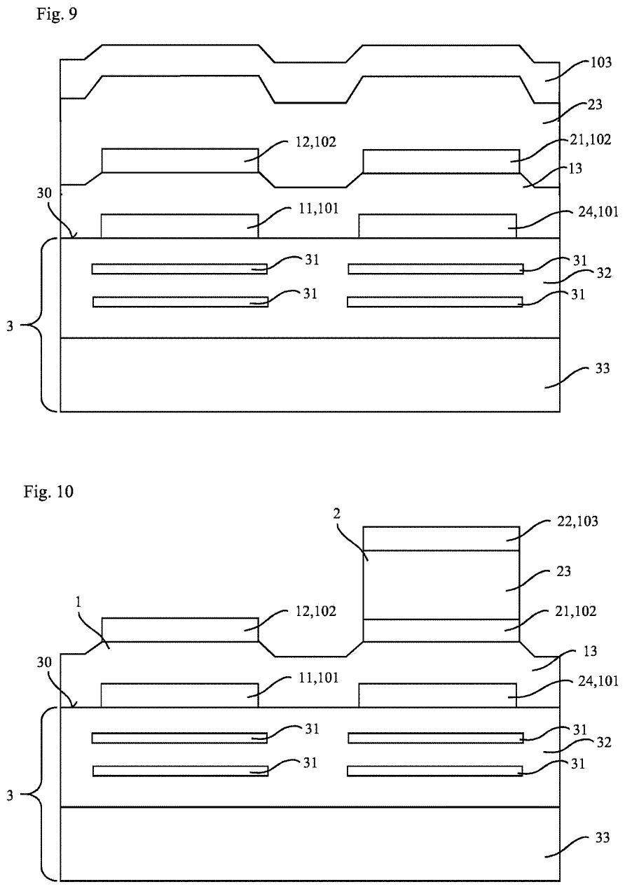

FIG. 9 shows an eighth position of the method, in which a third metallic layer 103 is deposited on the second piezoelectric layer 23. Again, the third metallic layer 103 may be deposited by sputtering or evaporation.

FIG. 10 shows a ninth position in the method, in which the third metal layer 103 is structured so that a top electrode 22 of the second BAW-resonator 2 is formed. Structuring is, for example, done by etching with the help of a mask. In the region of the first BAW-resonator 1, the third metal layer 103 is removed. Additionally, the second piezoelectric layer 23 is removed in the region of the first BAW-resonator 1. Also the second piezoelectric layer 23 may be removed by etching using a mask. After removing the second piezoelectric layer 23, the top electrode 12 of the first BAW-resonator 1 is exposed. FIG. 10 at the same time shows a finalized electric component. Particularly, the finalized electric component of FIG. 10 is identical to the electric component of FIG. 1.

FIG. 11 shows a further exemplary embodiment of the electric component in a cross-sectional view. The design is almost identical to that of the electric component of FIG. 1. The only difference is that no dummy electrode is present in the region below the second BAW-resonator 2. Such an electric component can be manufactured using the method described before. In the step of structuring the first metal layer 101, the first metal layer 101 is completely removed in the region of the second BAW-resonator.

The invention described herein is not limited by the description in conjunction with the exemplary embodiments. Rather, the invention comprises any new feature as well as any combination of features, particularly including any combination of features in the patent claims, even if said feature or said combination per se is not explicitly stated in the patent claims or exemplary embodiments.

### REFERENCE SIGN LIST

1 first BAW-resonator
2 second BAW-resonator
3 carrier substrate
11 bottom electrode of the first BAW-resonator
12 top electrode of the first BAW-resonator
13 first piezoelectric layer
21 bottom electrode of the second BAW-resonator
22 top electrode of the second BAW-resonator
23 second piezoelectric layer
24 dummy electrode
30 top side of the carrier substrate
31 layer
32 layer
33 base substrate
101 first electrode layer
102 second electrode layer
103 third electrode layer

1. An electric component comprising:
a first BAW-resonator;
a second BAW-resonator electrically connected to the first BAW-resonator; and
a carrier substrate with a top side on which the BAW-resonators are arranged, wherein:
the first and the second BAW-resonator each comprise a bottom electrode and a top electrode,
the bottom electrodes are in each case located between the carrier substrate and the respective top electrode,
a first piezoelectric layer is arranged between the top electrode and the bottom electrode of the first BAW-resonator and laterally extends from the first BAW-resonator, and
the second BAW-resonator is mounted on the first piezoelectric layer in a region laterally next to the first BAW-resonator and comprises a second piezoelectric layer between the top electrode of the second BAW-resonator and the bottom electrode of the second BAW-resonator.

2. The electric component according to claim 1, wherein the first piezoelectric layer and the second piezoelectric layer have different thicknesses.

3. The electric component according to claim 1, wherein a dummy electrode is located between the second BAW-resonator and the carrier substrate.

4. The electric component according to claim 3, wherein the bottom electrode of the first BAW-resonator and the dummy electrode lie laterally next to each other in a common plane.

5. The electric component according to claim 3, wherein the dummy electrode is not electrically connected to another element for the operation of the electric component.

6. The electric component according to claim 3, wherein the dummy electrode is completely enclosed by the first piezoelectric layer and the carrier substrate.

7. The electric component according to claim 1, wherein in a region between the bottom electrode of the second BAW-resonator and the carrier substrate, the first piezoelectric layer is in direct contact to the carrier substrate.

8. The electric component according to claim 1, wherein the top electrode of the first BAW-resonator and the bottom electrode of the second BAW-resonator lie next to each other in a common plane.

9. The electric component according to claim 1, wherein:
the electric component is or comprises an RF-filter, and
the first BAW-resonator is a serial resonator and the second BAW-resonator is a shunt resonator or vice versa.

10. The electric component according to claim 1, wherein the carrier substrate comprises layers of different acoustic impedances stacked above each other along a direction perpendicular to the top side.

11. The electric component according to claim 1, wherein the first and the second BAW-resonator have different resonant frequencies.

12. The electric component according to claim 1, wherein the electric component is a chip.

13. The electric component according to claim 1, wherein the first piezoelectric layer laterally extends beyond the top electrode and the bottom electrode of the first BAW-resonator.

14. A method for manufacturing an electric component, comprising:
providing a carrier substrate;
depositing a first electrode layer on a top side of the carrier substrate;
thereafter depositing a first piezoelectric layer on the first electrode layer;
thereafter depositing a second electrode layer on the first piezoelectric layer;
thereafter depositing a second piezoelectric layer on the second electrode layer;
thereafter depositing a third electrode layer on the second piezoelectric layer; and
thereafter removing the second piezoelectric layer in a region of a first BAW-resonator and keeping at least a portion of the third electrode layer and of the second piezoelectric layer in a region of a second BAW-resonator.

15. The method according to claim 14, wherein a bottom electrode of the first BAW-resonator is formed out of the first electrode layer.

16. The method according to claim 14, wherein a dummy electrode is formed out of the first electrode layer in the region of the second BAW-resonator.

17. The method according to claim 14, wherein a top electrode of the first BAW-resonator and a bottom electrode of the second BAW-resonator are formed out of the second electrode layer.

18. The method according to claim 14, wherein a top electrode of the second BAW-resonator is formed out of the third electrode layer.

19. The method according to claim 14, wherein the electrode layers and/or the piezoelectric layers are deposited by sputtering or vapor deposition.
